(19) United States
(12) Patent Application Publication
(10) Pub. No.: US 2026/0344449 A1
(43) Pub. Date: Oct. 29, 2026

(54) IMPROVING ALIGNMENT ACCURACY FOR HYBRID BOND INTERCONNECTS USING FLUOROPHORES

(71) Applicant: Intel Corporation, Santa Clara, CA (US)

(72) Inventors: Santosh Tripathi, Portland, OR (US); Madhav Gautam, Portland, OR (US); Vivek Chidambaram, Sengkang (SG); Jonathon Maner, Portland, OR (US); Jonathan Burk, Portland, OR (US); Alvin Gatimu, Hillsboro, OR (US); Sai Mylavarapu, Portland, OR (US); Steven Duggan, Hillsboro, OR (US); Shyam Ramalingam, San Jose, CA (US); Tuyen Tran, Portland, OR (US)

(73) Assignee: Intel Corporation, Santa Clara, CA (US)

(21) Appl. No.: 19/190,182

(22) Filed: Apr. 25, 2025

(51) Int. Cl. H10W 46/00; H10W 80/00; H10W 90/00; H10W 90/20

(52) U.S. Cl. CPC H10W 46/00; H10W 90/00; H10W 46/301; H10W 80/163; H10W 80/312; H10W 80/327; H10W 90/20; H10W 90/792

(57) ABSTRACT

Integrated circuit (IC) devices having direct-bonded dies. An IC device may include an IC substrate with a dielectric layer and a fluorophore between sidewalls of the dielectric layer. The fluorophore may be a quantum dot. The IC device may include a second IC substrate with a second fluorophore, the second IC substrate hybrid bonded with the first IC substrate fluorophore, and the first and second fluorophores vertically aligned. The first fluorophore may absorb light at a first wavelength and emit light at a second wavelength, and the second fluorophore may absorb light at the second wavelength and emit light at a third wavelength. The light at a third wavelength may be detected and used to align the first and second IC substrates, e.g., before direct bonding.

### BACKGROUND

Hybrid (e.g., direct metal-metal and dielectric-dielectric) bonding is becoming more common and increasingly necessary to enable the tighter interconnects required by next-generation integrated circuit (IC) products and packaging. The tighter pitches of direct-bonded interconnects may increase power and signal connection densities by a factor of a hundred or more (relative to typical copper microbumps), but conventional alignment techniques and equipment are not sufficiently precise to support the denser interfaces of upcoming products. Some wafer-to-wafer bonders can align to-be-bonded substrates more accurately than chip-to-chip bonders by utilizing expensive mechanical, optical, and image-processing resources (including litho overlay correction techniques), but even these resources are approaching theoretical limitations and come with the additional cost of reduced throughput (and some cannot feasibly be extended to die bonding). Self-alignment methods (e.g., using capillary effects) are being studied, but such processes would introduce multiple, significant challenges, including creating perfectly hydrophilic and hydrophobic surfaces, uniformly heating and evaporating tiny water droplets, etc.

New techniques, structures, and materials are needed to improve the alignment of IC substrates.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates cross-sectional profile views of an integrated circuit (IC) device having fluorophores in or on an IC substrate, in accordance with some embodiments;

FIGS. 2A and 2B illustrate cross-sectional profile views of an IC device having multiple IC substrates hybrid bonded, for example, coupled by direct bonds, in accordance with some embodiments;

FIG. 3 is a flow chart of methods for aligning IC substrates using fluorophores, in accordance with some embodiments;

FIGS. 4A, 4B, 4C, 4D, and 4E illustrate graphical, plan, and cross-sectional profile views of the aligning of IC substrates using fluorophores, describing various stages of aligning, in accordance with some embodiments;

FIG. 5 is a flow chart of methods for forming plugs (or other volumes) containing fluorophores in IC substrates, in accordance with some embodiments;

FIGS. 6A, 6B, 6C, 6D, 6E, and 6F illustrate cross-sectional profile views of an IC device having an alignment plug containing fluorophores between sidewalls of a dielectric layer and IC substrate, at various stages of manufacture, in accordance with some embodiments;

FIGS. 7A, 7B, 7C, 7D, 7E, and 7F illustrate cross-sectional profile views of an IC device having an alignment plug containing fluorophores between sidewalls of a dielectric layer, at various stages of manufacture, in accordance with some embodiments;

FIGS. 8A, 8B, 8C, 8D, 8E, and 8F illustrate cross-sectional profile views of an IC device having an alignment plug containing fluorophores between sidewalls 116, 117 of dielectric layer 142, at various stages of manufacture, in accordance with some embodiments;

FIG. 9 illustrates a diagram of an example data server machine employing an IC device having fluorophores in direct-bonded substrates; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve the alignment (and aligning) of integrated circuit (IC) substrates having tight metallization pitches, such as IC devices with direct (e.g., fusion) bonds.

Fluorophores may be used to align IC substrates to newly possible alignment tolerances, for example, <50 nm placement accuracy to enable the tight, dense pitches of hybrid bonding. The unique optical properties of fluorophores may provide a simple light signal that enables precise alignment of IC substrates without the extreme monetary and temporal costs of complex image processing otherwise needed for substrate alignments that, while approaching the precision of ~100 nm, are inferior to the disclosed alignment methods. No litho correction technologies are needed

IC dies and/or wafers (or other IC substrates) to be direct bonded may both have fluorophores that are aligned in order to precisely their host IC substrates. The IC substrates may have complementary fluorophores that operate at different wavelengths of light. An alignment system may interact with the complementary fluorophores by sourcing light at a first wavelength and by detecting light at a second (longer) wavelength. The first fluorophore in the first (e.g., lower) substrate may absorb the light sourced by the alignment system at the first wavelength and re-emit the light energy at an intermediate wavelength (e.g., a wavelength longer than the first wavelength and shorter than the second wavelength). A second fluorophore in the second (e.g., upper) substrate may absorb the light emitted by the first fluorophore (at the intermediate wavelength) and re-emit the light energy at the second wavelength (e.g., a wavelength longer than the first or intermediate wavelengths). Light energy at the second wavelength may be detected by the alignment system and used as a control signal to optimize the substrate alignment, for example, to a precision of <50 nm.

Any suitable fluorophores may be used. In many embodiments, quantum dots may be employed as the fluorophores, which may enable the tuning of the light wavelengths to be absorbed and emitted. In some embodiments, the quantum dots include gallium arsenide or indium arsenide.

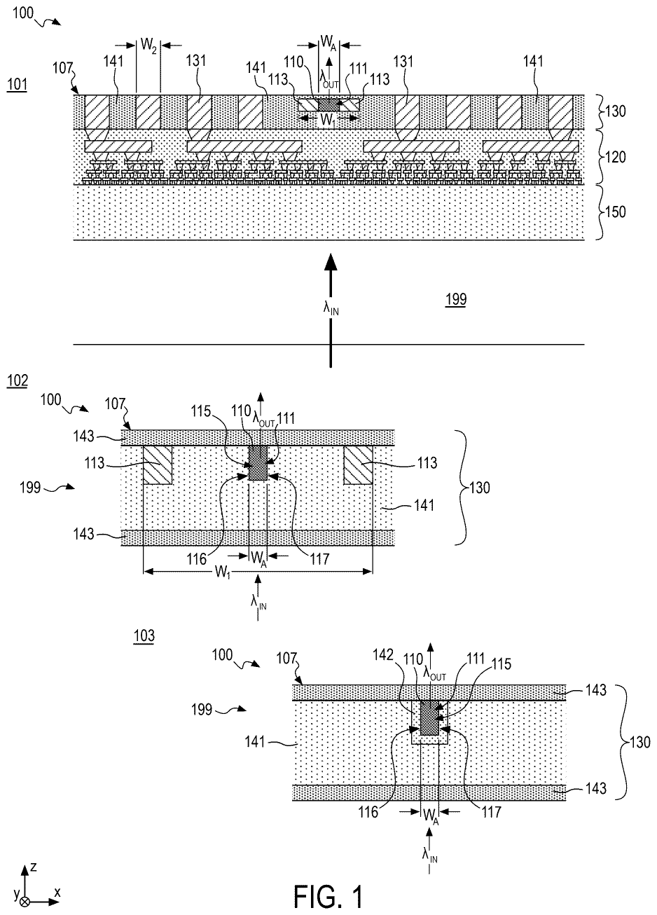

FIG. 1 illustrates cross-sectional profile views of an IC device 100 having fluorophores 111 in or on an IC substrate 199, in accordance with some embodiments. FIG. 1 shows views 101, 102, 103 through alignment plugs 110, which may include a significant amount (e.g., very many molecules) of fluorophores 111. Alignment plugs 110 (e.g., fluorophores 111) may enable the precise alignment of interconnect interfaces 131 of substrate 199, for example, with other interfaces 131 in another substrate 199 (e.g., an IC die or wafer). Interconnect interfaces 131 may be copper pads or other metallization structures, etc., that provide suitable conductive interfaces in hybrid-bonded IC substrates 199.

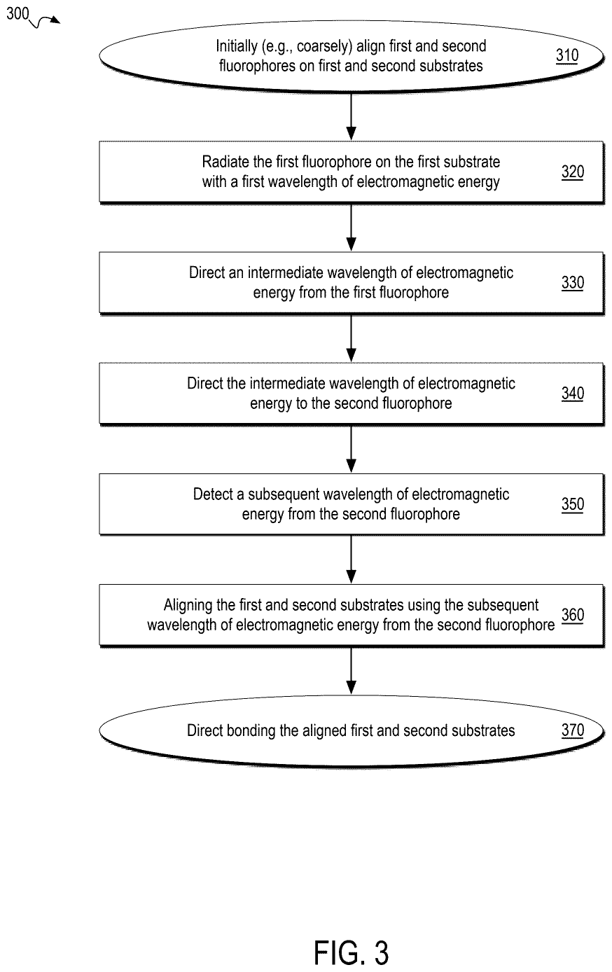

A fluorophore 111 is a fluorescent molecule or particle, e.g., of a chemical compound that can re-emit light upon excitation by light. Fluorophore 111 may absorb (and be excited by) light energy of a specific wavelength and re-emit light at a longer wavelength. The term “light” may refer broadly to electromagnetic radiation of any wavelength (whether visible or not), e.g., to include gamma rays, X-rays, microwaves, radio waves, etc. Either, neither, or both of the wavelengths absorbed and re-emitted by fluorophore 111 may be visible. The fluorophore 111 (and/or specific wavelengths of light) to be used may depend on the transmission characteristics of substrates 199. For example, in the case of a silicon substrate 199, infrared (IR) or X-ray light (both non-visible) would transmit through substrate 199 and may advantageously be used. Fluorescence, the emission of (e.g., visible) light by a substance that has absorbed light, is distinguished from phosphorescence by the time scale at which the luminescent material emits light following the cessation of the exciting radiation. Fluorescent materials generally cease to glow nearly immediately when the radiation source stops, while phosphorescent materials continue to emit light for some time after the radiation stops. These characteristics of fluorophores 111 enable the novel alignment processes of methods 300 (e.g., as described at least at FIG. 3).

IC device 100 includes substrate 199. Substrate 199 includes interface level 130, interconnect level 120, and device layer 150, for example, over a base of semiconductor material. Interface level 130 includes interconnect interfaces 131 on upper surface 107 and through dielectric layer 141. In many embodiments, fluorophores 111 are adjacent surface 107, e.g., on, at, or just below upper surface 107. Substrate 199 includes fluorophores 111 adjacent surface 107 in alignment plug 110. In the exemplary embodiment of FIG. 1, alignment plug 110 is in interface level 130, within the extent (e.g., within width W₁) of a fiducial structure 113. Interface level 130 includes dielectric layer 141 and multiple interconnect interfaces 131 through layer 141. Interface level 130 may include many interconnect interfaces 131, e.g., in an array of thousands of interconnect interfaces 131 on surface 107, including interconnect interfaces 131 not shown in the x-z plane of cross-sectional profile view 101. Interconnect interfaces 131 may be packed tightly with a very small pitch enabled by fluorophores 111 in alignment plugs 110. Interface level 130 may include multiple, even many, plugs 110 and fiducial structures 113, e.g., as necessary to satisfactorily align substrates 199. For example, substrate 199 may extend in both x-directions, and one or more other plugs 110 and fiducial structures 113 may be included in substrate 199, e.g., on the same x-z plane.

Alignment plug 110 need not be within interface level 130 or the extent of fiducial structure 113. In many embodiments, alignment fluorophores 111 in one or more plugs 110 are in one or more of levels 120, 130 and layer 150, and structures 113 are in a different set of levels 120, 130 and layer 150. In some embodiments, fluorophores 111 and plugs 110 are in device layer 150 (or adjacent layer 150 in level 120), and fiducial structures 113 are in a level 130 (or adjacent level 130 in level 120). In some embodiments, structures 113 are in a level 120 or 130 (not shown) on a backside of substrate 199, opposite the illustrated levels 120, 130.

Fluorophores 111 are adjacent and between interconnect interfaces 131 in dielectric layer 141 and substrate 199. Fluorophores 111 are in alignment plug 110, surrounded by fiducial structure 113. In many embodiments, plug 110 includes a volume of a dielectric material and includes fluorophores 111 (e.g., suspended or otherwise mixed) in the volume of the dielectric material. The dielectric material may be the same or a different dielectric material as the material of dielectric layer 141. In many embodiments, layer 141 is of (or includes) a material substantially transparent to light, e.g., that allows for the illumination or radiation of fluorophores 111 from above or below and/or for the illumination or radiation by fluorophores 111 of other structures, above or below.

Again, the “light” may be visible electromagnetic radiation or electromagnetic radiation of a non-visible wavelength, so the transparency of layer 141 may be at the wavelength(s) of interest, but need not be over the entire spectrum of light. In many embodiments, fluorophore 111 is capable of absorbing light energy at an input wavelength λ_{IN} and emitting light energy at a longer output wavelength λ_{OUT}, and both input and output wavelengths λ_{IN}, λ_{OUT} are longer than 700 nm. Wavelengths λ_{IN}, λ_{OUT} longer than visible wavelengths (e.g., longer than 700 nm) and shorter than microwaves (e.g., shorter than ~1 mm) are IR wavelengths, at which wavelengths many typical materials (e.g., silicon) of substrate 199 may be transparent. In some embodiments, both input and output wavelengths λ_{IN}, λ_{OUT} are shorter than 10 nm (e.g., X-rays), at which wavelengths many typical materials (e.g., silicon) of substrate 199 may be transparent. Although fluorophore 111 absorbs light energy at wavelength λ_{IN} (e.g., through substrate 199) and emits light energy at wavelength λ_{OUT} (e.g., out of substrate 199 at surface 107) in view 101, in some embodiments, fluorophore 111 absorbs light energy down through surface 107 (e.g., at a wavelength λ_{IN}) and emits light energy down through substrate 199 (e.g., at a longer wavelength λ_{OUT}). In many embodiments, fluorophore 111 emits light in multiple directions (e.g., up and down) at longer wavelength λ_{OUT}.

Fluorophore 111 may be any suitable fluorescent molecule or particle. In some embodiments, fluorophore 111 is a reactive or conjugated dye. Advantageously, fluorophore 111 is sufficiently thermally, chemically, mechanically, etc., rugged to withstand semiconductor manufacturing processes (such as dry and wet etches, chemical mechanical polish (CMP)). Even some organic fluorophores (such as silicon substituted bis-benzannulated rhodamine dyes) have demonstrated sufficient resilience to, e.g., high temperature. In some embodiments, fluorophore 111 is an inorganic fluorophore 111, which may provide exceptional chemical stability and resistance to mechanical stress.

Fluorophore 111 may be a quantum dot, for example, a semiconductor particle or nanocrystal a few nanometers in size (e.g., 2-10 nm in diameter, ~100-100,000 atoms), which may have optical and electronic properties that (e.g., because of quantum mechanical effects) differ from those of larger particles. In many embodiments, fluorophore 111 is a quantum dot of (or including) indium and arsenic (e.g., in InAs) and/or gallium and arsenic (e.g., in GaAs). Other (e.g., semiconductor) material(s) may be employed. As with other fluorophores, when a quantum dot is illuminated by light, an electron in the quantum dot may be excited to a higher-energy state. In the case of a quantum dot, this excitation corresponds to the transition of an electron from the valence band to the conduction band. The excited electron can return to the valence band, releasing energy as light, and the wavelength of that light (e.g., the color, if visible) depends on the energy difference between the discrete energy levels of the quantum dot in the conduction and valence bands.

A quantum dot fluorophore 111 may, therefore, be a semiconductor structure capable of confining electrons in three dimensions and at discrete energy levels. Quantum dot fluorophores 111 may be particles that behave much as individual atoms and with properties that can be manipulated. The absorption and emission wavelengths of these fluorophores 111 may be tunable by controlling the size of fluorophores 111, which may be beneficial, e.g., as described at least at FIG. 3 and methods 300. For example, a quantum dot fluorophore 111 may be sized to enable the absorbing and emitting of light at IR wavelengths, making for a beneficially high signal-to-noise ratio given other structures and materials embedded in a dielectric stack (e.g., highly doped silicon).

Fluorophores 111 may be deployed in dielectric layer 141 and substrate 199 in any suitable fashion. Layer 141 may include any suitable dielectric material(s), e.g., for providing mechanical support for, and electrical isolation between, interconnect interfaces 131. Advantageously, layer 141 provides suitable dielectric faces on surface 107 for direct bonding with complementary dielectric surfaces on a similar substrate 199. In many embodiments, layer 141 includes silicon and oxygen, for example, in a silicon oxide (such as SiO₂, etc.). Views 102, 103 show possible embodiments of plugs 110 in transparent layer 141.

View 102 illustrates plug 110 in interface level 130, but other positions may be employed, such as device layer 150 (or adjacent layer 150 in level 120, as described at view 101). Plug 110 includes a volume of a dielectric material 115 and includes one or more fluorophores 111 in the volume of dielectric material 115 (e.g., in a mixture). Plug 110 may be a fluorescent plug 110 (e.g., a fluorescent layer) that includes very many (e.g., thousands or millions, billions, etc., of) molecules of fluorophores 111 in a transparent material 115. Fluorescent layer or plug 110 includes fluorophores 111 and dielectric material 115 between sidewalls 116, 117 of dielectric layer 141. Dielectric layer 141 may be a fluorescent layer 141 containing multiple fluorescent layers or plugs 110.

Sidewalls 116, 117 of fluorescent layer or plug 110 are separated by the lateral distance of width W_{A} of plug 110. In many embodiments, width W_{A} is 30 nm or less, which may be suitably small to enable sufficiently precise alignment of substrate 199 (for example, with another substrate 199). In some embodiments, width W_{A} is 20 nm or less, which may enable more alignment precision than a wider plug 110. Narrower plugs 110 (e.g., with smaller widths W_{A}) may be correspondingly taller to ensure plug 110 is capable of holding a sufficient quantity of fluorophores 111, for example, to enable the alignment processes of methods 300. Note that layer or plug 110 may have any suitable aspect ratio, e.g., not limited by the examples shown in FIG. 1, etc., which may not be to scale. For example, fluorescent plug 110 may be a fluorescent layer with a depth deeper (e.g., greater) than width W_{A} of plug 110, or plug 110 may be a fluorescent layer with a wider width W_{A} than depth of plug 110.

A shape or general geometry of plug 110 (including of substantially vertical sidewalls 116, 117) may aid in the absorption and/or emission of light, e.g., from a source below and/or to a fluorophore or other detector above, respectively. In some embodiments, plug 110 has non-vertical sidewalls 116, 117 (or other features), e.g., to aid in the absorption from a source or emission of light towards another plug 110 or other detector. In some embodiments, fiducial structure 113 (e.g., around alignment plug 110) includes a structure (for example, of concentric circles) that aids in the absorption from a source or emission of light towards another plug 110 or other detector. Concentric structures (e.g., at different heights or levels, for example, conforming to conical, parabolic, etc., profiles) or other structures may improve the efficiency of the absorption or emission of light by focusing the light.

Dielectric material 115 may be or include any suitable material(s). Dielectric material 115 is advantageously a very transparent material 115 (at least at the wavelengths of interest), for example, to enable the transmission of light to and from fluorophores 111 and so the alignment of interconnect interfaces 131 and substrate 199 with complementary structures. In many embodiments, material 115 serves as a base medium for fluorophores 111, e.g., during installation or delivery (e.g., dispensing) of fluorophores 111 into substrate 199 between sidewalls 116, 117 of dielectric layer 141. For example, dielectric material 115 may be classified (post-processing) as a glass, such as an acrylic glass or non-crystalline vitreous substance, e.g., initially applied as a resin before thermosetting (or other crosslinking) into a transparent thermoplastic, etc. In some such embodiments, transparent material 115 includes a methyl methacrylate (MMA), e.g., in PMMA (poly MMA) and/or with 2-hydroxyethyl methacrylate (HEMA) in HEMA:MMA. These and other polymer-based materials 115 may be thermally stable up to multiple hundreds of degrees (even Celsius). In many embodiments, plug 110 includes flowable dielectric materials, such as (or similar to) those used in spin-on dielectrics, including polysilicates, polysiloxanes, polysilsesquioxanes, polyhydrocarbons, or polyimides. In some embodiments, plug 110 includes an inorganic material 115, e.g., capable of withstanding processing temperatures subsequent to the forming of alignment plugs 110. In some such embodiments, plug 110 includes silicon and oxygen, for example, in an oxide of silicon. In some embodiments, plug 110 includes an organic material 115, for example, as enabled by low-temperature bonding processes, such as fusion or direct bonding.

Substrate 199 may include a dielectric layer 143 under dielectric layer 141, e.g., as an etch-stop layer 143. In some embodiments, substrate 199 includes a capping layer 143 over plug 110 and dielectric layer 141. In some such embodiments, substrate 199 includes another dielectric layer 141 over layer 143. Layer(s) 143 may include any suitable dielectric material(s). Dielectric layers 141, 143 may be of the same dielectric material or of differing materials, e.g., with etch selectivities. Layer 143 may provide a dielectric surface on surface 107 for direct bonding with a similar substrate 199. In some embodiments, dielectric layer 143 includes silicon and oxygen, for example, in a silicon oxide (such as SiO₂, etc.). In some embodiments, layer 143 includes silicon and nitrogen, for example, in a silicon nitride. In some embodiments, insulator layer 143 includes silicon, carbon, and nitrogen (for example, in SiCN). In some such embodiments, the carbon content of layer 143 is less than 30%. In some embodiments, dielectric layer 143 includes silicon, carbon and oxygen (for example, in SiCO).

Alignment plug 110 (with fluorophores 111) is adjacent fiducial structure 113 in substrate 199. In some embodiments, as in view 102, plug 110 is within the borders or span (e.g., within width W₁) of alignment structure 113. Structure 113 may have a minimum necessary size (e.g., dimension or width W₁), for example, to support alignment of substrates 199. The minimum width W₁ of fiducial structure 113 may be significantly reduced relative to conventional fiducial structures, for example, enabled by fluorophores 111 and the alignment processes of methods 300, which may not require as large of fiducial structures. Conventionally, fiducial structures with x- and y-dimensions of about 30-50 μm may be required, e.g., for alignment purposes, even though copper pad sizes may be much smaller (for example, 5 μm or less, e.g., 4.5 μm). With alignment fluorophores 111, fiducial structure 113 (and width W₁) may be as small or smaller than interconnect interfaces 131 (and width W₂, as shown at view 101). In some embodiments, width W₁ of fiducial structure 113 is 4.5 μm or less, which may provide significant area savings in substrate 199 and additional layout flexibility (e.g., by not providing keep-out areas that need to be routed around). Fiducial structures 113 and interfaces 131 having similar sizes (such as width W₁) may be preferable to prevent or minimize dishing during CMP of surface 107.

Fluorophores 111 and alignment plug 110 may support the alignment of substrates 199 to such precision as to enable the employment of interfaces 131 (e.g., copper pads) with even smaller dimensions, such as a width W₂ of 0.5 μm or less. By utilizing alignment fluorophores 111 and plug 110, fiducial structure 113 (and width W₁) may be as small or smaller than even shrunken interconnect interfaces 131 (and width W₂). In some embodiments, widths W₁, W₂ of structure 113 and interfaces 131 are both 0.5 μm or less.

View 103 shows layer or plug 110, which may be smaller (e.g., with a smaller width W_{A}) or about the same size (e.g., with approximately equal widths W_{A}) as plug 110 in view 102. Plug 110 may be similar to layer or plug 110 in view 102, but in view 103, fluorophores 111 and dielectric material 115 are between sidewalls 116, 117 of dielectric layer 142, which is at least somewhat conformal in dielectric layer 141. Layer 142 may enable a layer or plug 110 having a smaller width W_{A} (e.g., in a same-sized hole in layer 141) or a same width W_{A} in a larger hole in layer 141, for example, to provide a plug 110 small enough to ensure sufficient alignment precision. In some embodiments, width W_{A} is 20 nm or less.

Layer 142 may include any suitable dielectric material(s), e.g., that allows the transmission of light to fluorophores 111 in plug 110. In some embodiments, layer 142 includes silicon and oxygen, for example, in a silicon oxide (such as SiO₂, etc.). In some embodiments, layer 142 includes silicon and nitrogen, for example, in a silicon nitride.

Returning to view 101, as described, interconnect interfaces 131 in interface level 130 may be copper pads or other metallization structures, etc., that provide suitable conductive interfaces in hybrid-bonded IC substrates 199. Interfaces 131 may be of or include any suitable material, such as a metal or other conductive material, e.g., for conveying electrical power and/or signals into and out of substrate 199. In many embodiments, interfaces 131 include copper, but other materials (including other metals) may be used. Interconnect interfaces 131 may have a substantially flat face on surface 107, for example, available for bonding with another substrate 199. Interconnect interfaces 131 may have a width W₂ of 5 μm or less and a similarly sized pitch between interfaces 131 (e.g., of approximately 5 μm). Interfaces 131 may be coupled with metal lines and/or vias in interconnect level 120.

IC substrate 199 may include a metallization or interconnect level 120, for example, over a device layer 150, coupling layer 150 with interface level 130. Interconnect level 120 may include metal lines and vias that couple structures in device layer 150 with interconnect interfaces 131 in interface level 130 and with electrical power and/or signals through interconnect interfaces 131. As used herein, the term “metallization level” or “interconnect level” describes a level or layer primarily with interconnections or wires that provide electrical routing, generally formed of metal or other electrically conductive material. Metallization level 130 may be formed by any suitable means and may include any suitable material(s). In many embodiments, metallization layers in level 130 include one or more of copper, gold, tantalum, cobalt, tungsten, ruthenium, molybdenum, aluminum, and nickel, including in alloys. In some embodiments, level 130 includes nitrides of metals, e.g., of tantalum or titanium. Level 130 may include other electrically conductive materials, including non-metals.

Adjacent metallization layers (e.g., within level 120) may be formed of different materials and by different methods. Metallization or interconnect level 120 may generally be over device layer 150, including in a stack of multiple interconnect layers over layer 150. Adjacent metallization layers (e.g., within level 120) are interconnected by vias that may be characterized as part of the metallization layers or between the metallization layers. As shown, in some embodiments, front-side metallization level 120 is over and immediately adjacent device layer 150. The back-side is then the opposite side, which may be exposed during processing by attaching the front-side to a carrier wafer and exposing the back-side (e.g., by back-side grind or etch operations) as known in the art. In some embodiments (not shown), the back-side may also include an interconnect level 120 and, in some embodiments, an interface level 130.

Device layer 150 may include metallization and other interconnect features, but device layer 150 may be the layer 150, or one of the two or few layers 150, containing the all or the majority of the transistors (not shown) and/or memory cells (not shown) in IC substrate 199. Device layer 150 may be at or adjacent a base from which both the front-and (in some embodiments) back-sides are built up (e.g., first in one direction and then the opposite). While transistors are often not deployed in layers meant primarily for interconnections, transistor structures may be deployed in metallization layers over device layers.

Substrate 199 may include any suitable material or materials. Substrate 199 may be an IC substrate 199, such as an IC die or wafer. In some examples, substrate 199 may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures may be over a dielectric layer over other (e.g., semiconductor) materials, for example, in a device layer under an interconnect network including multiple interconnect levels of metallization lines and vias. IC device 100 may be a monolithic integrated circuit, e.g., consisting of a single silicon (or other semiconductor or insulator) substrate 199, or may include multiple IC substrates 199, e.g., in a 2.5D IC device 100 or 3D (three-dimensional) IC device 100, etc. A 2.5D IC device uses advanced packaging techniques that combine multiple IC dies in a single-package device without stacking the dies into a “3D IC,” e.g., with through-silicon vias (TSVs).

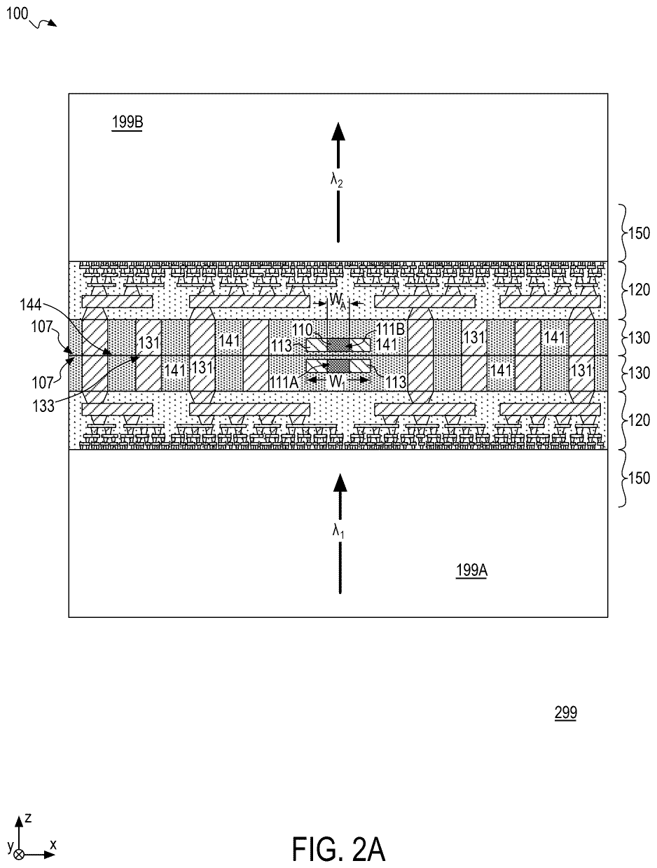

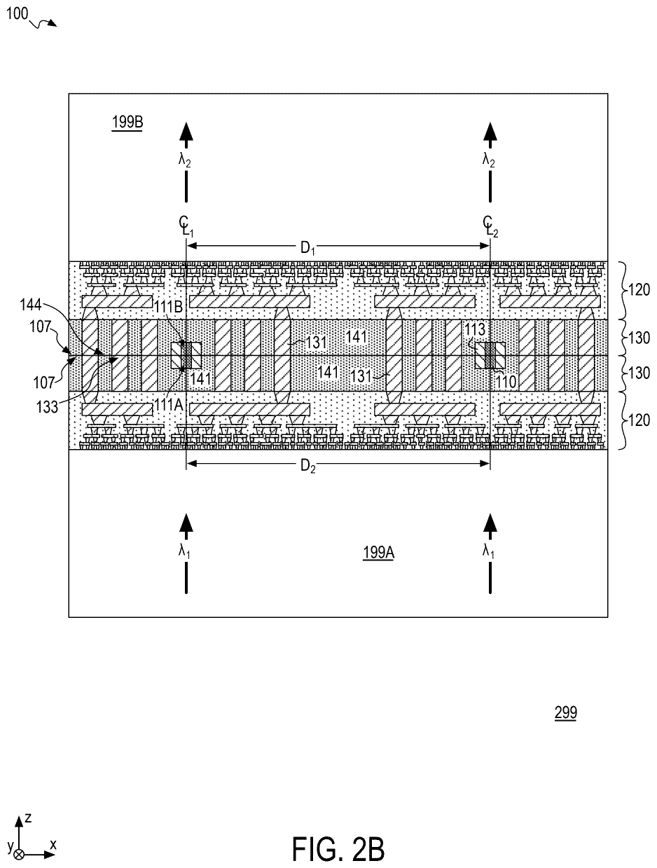

FIGS. 2A and 2B illustrate cross-sectional profile views of IC device 100 having multiple IC substrates 199 hybrid bonded, for example, coupled by direct bonds 133, 144, in accordance with some embodiments. Fluorophores 111 (and alignment plugs 110 and structures 113) in upper and lower substrates 199B, 199A are vertically aligned. Substrates 199 are coupled by fusion bonds 133, 144, but possible light energy wavelengths λ₁, λ₂ are shown as if during alignment methods 300 (e.g., radiating and being re-emitted from fluorophores 111 in lower and upper substrates 199A, 199B, respectively). An intermediate wavelength (not shown) may be emitted by the lower fluorophores 111A in lower substrate 199A (e.g., upon absorption of wavelength λ₁) and absorbed by the upper fluorophores 111B in upper substrate 199B (e.g., causing emission of wavelength λ₂). For example, wavelength λ₁ may be an input wavelength to substrate 199A (e.g., like wavelength λ_{IN} at FIG. 1), wavelength λ₂ may be an output wavelength from substrate 199B (e.g., like wavelength λ_{OUT} at FIG. 1), and the (not shown) intermediate wavelength may be an output wavelength from substrate 199A and an input wavelength to substrate 199B.

FIG. 2A shows IC device 100 having first and second (e.g., lower and upper) substrates 199 coupled at interconnect interfaces 131 and surfaces 107. Substrates 199 are hybrid bonded at surfaces 107, by metal-metal fusion bonds 133 coupling interconnect interfaces 131 and by dielectric-dielectric fusion bonds 144. Device 100 includes adjacent fluorophores 111 (e.g., fluorophores 111A, 111B) on the coupled substrates 199. Fluorophore 111A on the first (e.g., lower) substrate 199A is adjacent and vertically aligned with (e.g., under) fluorophore 111B on the second (e.g., upper) substrate 199B. Fluorophores 111A, 111B are both adjacent bonded surfaces 107. Fluorophores 111A, 111B may be complementary fluorophores 111, for example, with fluorophore 111A emitting light at an intermediate wavelength readily absorbed by fluorophore 111B.

Alignment plugs 110 and fiducial structures 113 may be much as described at FIG. 1 (for example, with plugs 110 having widths W_{A} less than 30 nm or less and structures 113 having widths W₁ of less than 4.5 μm) and with lower plug 110 and structure 113 vertically aligned with upper plug 110 and structure 113 (e.g., at centerlines and edges of plugs 110 and structures 113).

Upper and lower substrates 199B, 199A are direct bonded (e.g., fusion bonded). For example, metallization features (such as interconnect interfaces 131) on abutting surfaces 107 may be metallurgically interdiffused. In some embodiments, IC substrates 199 are hybrid bonded. In some such embodiments, dielectric material (e.g., of layer 141, between interfaces 131) on abutting surfaces 107 is chemically bonded (e.g., via Si—O—Si condensation bonds).

IC device 100 may include or be coupled to a substrate or other host component 299. Host component 299 may be a package substrate, an interposer, an IC die, etc. For example, substrates 199 may be IC dies, lower substrate 199A may be coupled (e.g., soldered or otherwise bonded) to host component 299, and both substrates 199 may be coupled to a power supply (not shown) through host component 299.

Host component 299 is a planar platform and may include dielectric and metallization structures. Host component 299 mechanically supports and electrically couples one or more IC devices 100. At least one side of host component 299 includes substrate interconnect interfaces for bonding to one or more IC devices 100. IC device 100 may be direct bonded, e.g., hybrid bonded, to host component 299 or otherwise bonded, e.g., by optional solder bumps. For example, a backside of substrate 199A may include interconnect and interface levels 120, 130 (not shown) under device layer 150, and interconnect interfaces 131 (not shown) in level 130 may be bonded with host substrate or component 299. The opposite side of host component 299 may include similar interfaces, e.g., copper pads for socketing and/or solder bumps for bonding device 100 to a host component, such as a printed circuit board (PCB). Host component 299 may be any host component with substrate interconnect interfaces, such as a package host component 299 or interposer, etc. Host component 299 may itself be a die. In many embodiments, host component 299 includes organic dielectric(s), such as a resin or other polymer, between metallization layers.

FIG. 2B shows IC device 100 having multiple alignment plugs 110 with fluorophores 111 in each of upper and lower substrates 199B, 199A hybrid bonded at surfaces 107. Substrates 199 are hybrid bonded by direct metal-metal bonds 133 coupling interconnect interfaces 131 and by direct dielectric-dielectric bonds 144. Multiple fluorophores 111 (and fiducial structures 113) in each of upper and lower substrates 199 are vertically aligned with corresponding fluorophores 111 in the corresponding substrates 199. Upper and lower IC substrates 199B, 199A have alignment plugs 110 with fluorophores 111 vertically aligned on a first centerline CL₁. For example, vertically aligned plugs 110 and fluorophores 111 may be on centerlines within 5 nm of the corresponding plugs 110 and fluorophores 111. Upper and lower IC substrates 199B, 199A have alignment plugs 110 with fluorophores 111 vertically aligned on a second centerline CL₂. The upper plugs 110 and fluorophores 111B on centerlines CL₁, CL₂ are separated by a distance D₁ equal to a distance D₂ separating lower plugs 110 and fluorophores 111A on centerlines CL₁, CL₂.

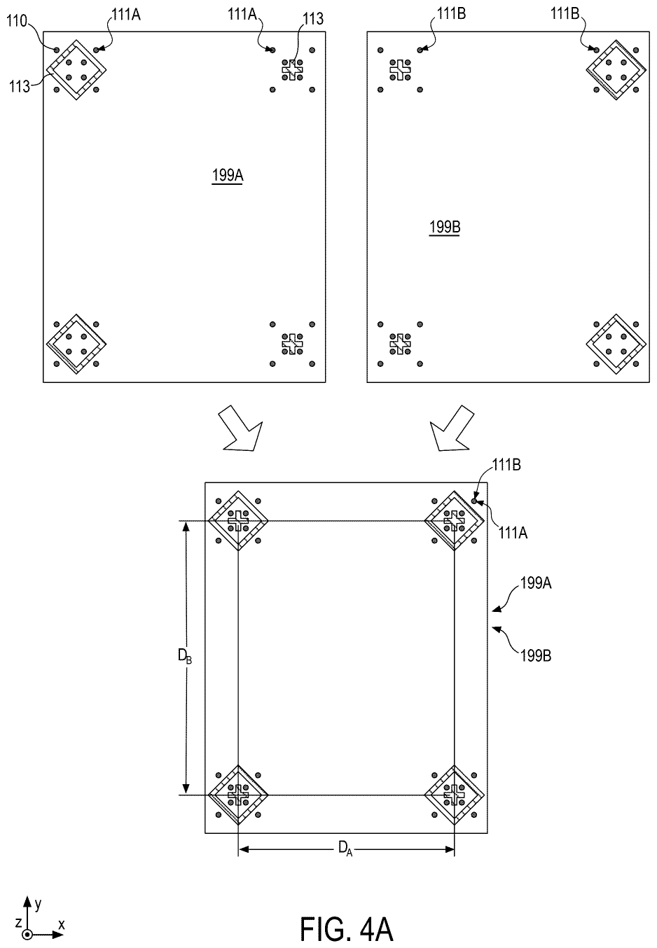

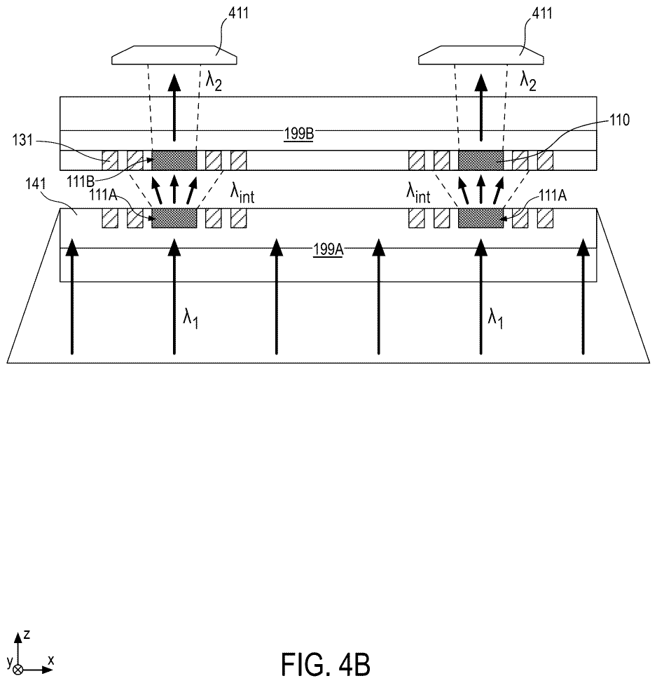

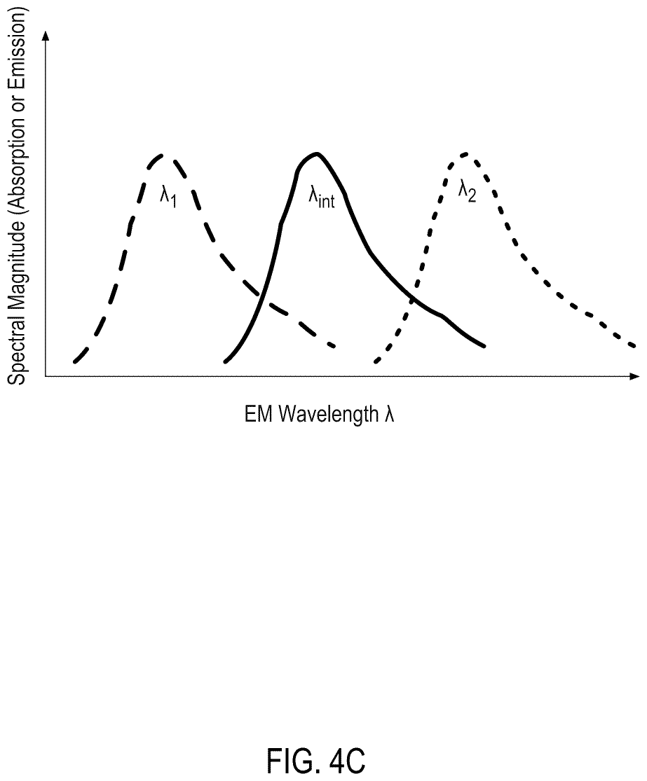

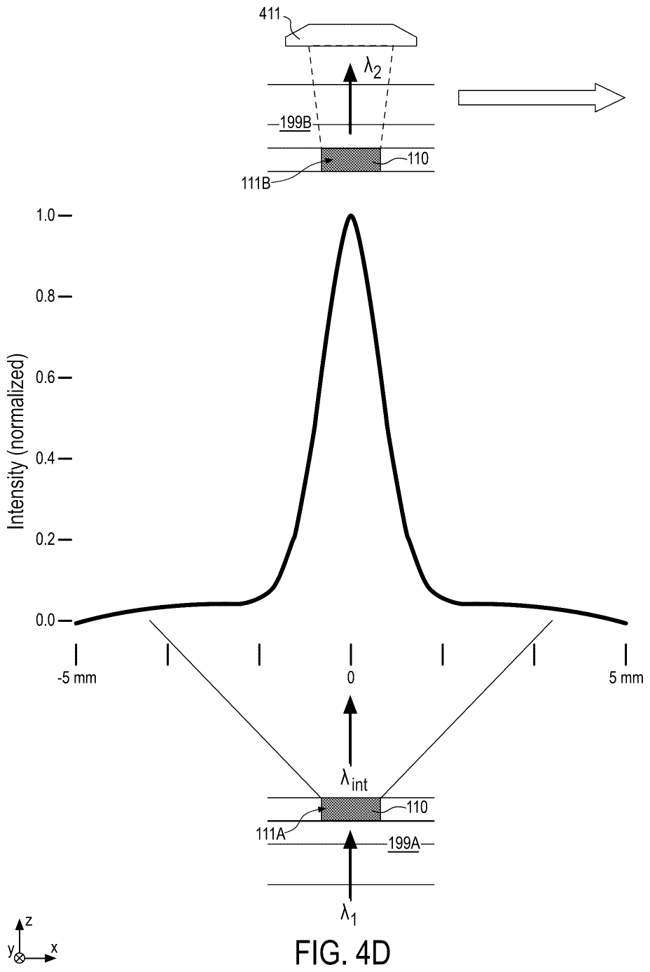

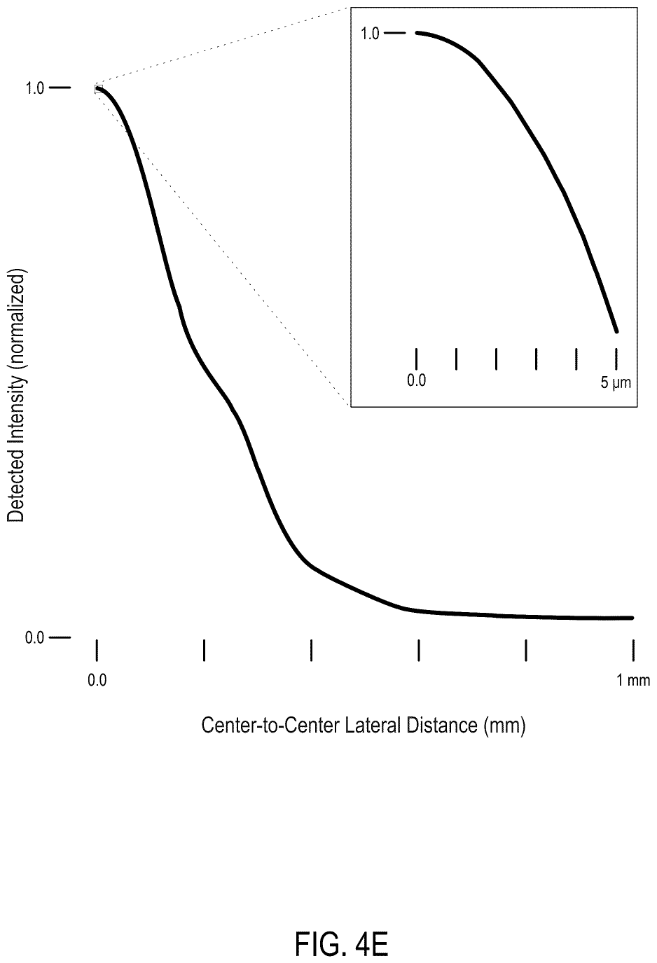

Although a single alignment plug 110 is shown within the bounds of each fiducial structure 113, plugs 110 and fluorophores 111 may be deployed in multiple (e.g., many) aligned locations on both substrates 199. In many embodiments, an array of plugs 110 containing fluorophores 111 are in and/or around each of fiducial structures 113 (as shown at FIG. 4A). In many embodiments, an alignment plug 110 is adjacent and between interconnect interfaces 131. In some embodiments, an alignment plug 110 is within an alignment structure 113 adjacent and between interconnect interfaces 131.

FIG. 3 is a flow chart of methods for aligning IC substrates using fluorophores, in accordance with some embodiments. Methods 300 include operations 310-360. Some operations shown in FIG. 3 are optional. Additional operations may be included. FIG. 3 shows an example sequence, but the operations can be done in other orders as well, and some operations may be omitted. Some operations can also be performed multiple times before other operations are performed. Some operations may be included within other operations so that the number of operations illustrated FIG. 3 is not a limitation of the methods 300.

FIGS. 4A, 4B, 4C, 4D, and 4E illustrate graphical, plan, and cross-sectional profile views of the aligning of IC substrates 199 using fluorophores 111, describing various stages of aligning, in accordance with some embodiments. FIGS. 4A-4E show possible examples of structures, as well as illustrative data plots, during an embodiment of a practice of methods 300 of FIG. 3.

Returning to FIG. 3, methods 300 begin at operation 310 with an optional initial aligning of first and second fluorophores in first and second (e.g., upper and lower) substrates. The first and second substrates may be IC dies or wafers, e.g., much as described of substrate 199 at FIG. 1, for example, with the first fluorophore(s) in the first, lower substrate and the second fluorophore(s) in the second, upper substrate. The first and second substrates may be aligned by any suitable means. The initial aligning of the first and second substrates may be by mechanical positioning (e.g., based on pick-and-place tooling and by substrate edges, etc.). In many embodiments, the first and second substrates (and the first and second fluorophores) are aligned to an accuracy (or proximity) of ~5 μm, which may be considered a crude or coarse alignment. This coarse alignment can be done at a quicker throughput than typical alignment processes because, e.g., the coarse alignment does not require high-level, post-image processing techniques and optimization. In many embodiments, an optics system is used for the coarse alignment of the first and second substrates (e.g., by aligning corresponding first and second fiducial marks), but without a need for slow and expensive image processing.

For example, a first camera (e.g., an up-looking camera) may capture an image of a first substrate (e.g., an IC chip/die) picked up on a bond head while a second camera (e.g., a down-looking camera) is used to capture an image of a second substrate (e.g., an IC wafer). A misalignment vector may be determined from these images and an appropriate offset then applied. This operation of the alignment process may be at a higher run rate (throughput) than conventional high-alignment accuracy bonders and without expensive optimization of the vision system and without higher resolution optics. Furthermore, this novel, relatively inexpensive, high-throughput process obviates the need for yet-to-be-realized self-alignment methods, for example, those dependent on capillary effects.

FIG. 4A illustrates plan views of unaligned and coarsely aligned IC substrates 199 having vertically aligned plugs 110 with fluorophores 111, in accordance with some embodiments, for example, before and after a performance of aligning operation 310. Complementary fiducial structures 113 are in top and base substrates 199B, 199A and create overlay structures 113 for IR metrology. Much of substrates 199B, 199A may be transparent to light at, e.g., IR or X-ray wavelengths, which may enable the aligning of overlapping structures 113 in top and base substrates 199B, 199A.

Base IC substrate 199A includes fluorophores 111A separated by first and second distances D_{A}, D_{B}, and top IC substrate 199B includes fluorophores 111B separated by the same first and second distances D_{A}, D_{B}. Base substrate 199A includes fluorophores 111A, top substrate 199B includes fluorophores 111B, and fluorophores 111A, 111B are vertically aligned. In some embodiments, alignment plugs 110 are within the borders or span of an alignment structure 113. In some embodiments, an alignment structure 113 is between plugs 110, for example, within an array of plugs 110. In some such embodiments (e.g., as shown in FIG. 4A), an alignment structure 113 is between first and second plugs 110 and closer to each of the first and second plugs 110 than the first plug 110 is to the second plug 110. Identical arrays of plugs 110 containing fluorophores 111 are in and/or around each of fiducial structures 113, e.g., fluorophores 111A in and/or around fiducial structures 113 in base substrate 199A and fluorophores 111B in and/or around the complementary fiducial structures 113 in top substrate 199B.

FIG. 4B shows base and top (or lower and upper) substrates 199A, 199B at least coarsely aligned, in accordance with some embodiments, for example, following a performance of aligning operation 310. Fluorophores 111A in lower substrate 199A are vertically aligned (e.g., at least coarsely) under fluorophores 111B in upper substrate 199B.

Returning to FIG. 3, methods 300 continue at operation 320 with radiating a first fluorophore in or on a first substrate with a first wavelength of electromagnetic energy. In many embodiments, the first fluorophore absorbs the electromagnetic energy of the first wavelength, and the first fluorophore re-emits electromagnetic energy at an intermediate wavelength longer than the first wavelength. Fluorophore properties may be utilized to align to nm scale, e.g., after an initial/coarse alignment (e.g., of ~5 μm) is performed. The first fluorophore may be radiated by any suitable means, for example, by a system light source providing light (electromagnetic) energy at least at the first wavelength. The system light source advantageously has a much greater intensity at the first wavelength than at other wavelengths (such as the (intermediate) wavelength to be absorbed by the second fluorophore). At this radiating operation, light (e.g., IR light) may be transmitted through a substrate (e.g., silicon or another semiconductor) layer in the bottom wafer (or die, etc.). In many embodiments, the light is IR light (which advantageously may be transmittable through many IC substrates), but the light may be at any suitable wavelength. For example, in some embodiments, the light is X-ray light, which may be suitable, e.g., transmittable through many IC substrates. The first fluorophore, in the bottom wafer or die, is designed to selectively absorb the incident (e.g., IR) light at a specific wavelength (e.g., a wavelength λ₁). The choice of the light source may be tailored to match the absorption wavelength, ensuring efficient absorption by the first fluorophore.

FIG. 4B shows the emission of electromagnetic energy (light) at wavelength λ₁ by a light source below substrate 199A and towards the first fluorophores 111A, in accordance with some embodiments, for example, during a performance of radiating operation 320. Although the first fluorophores 111A, the first substrate 199A, and the light source of wavelength λ₁ are under the second fluorophores 111B and the second substrate 199B in FIG. 4B, the light source and first fluorophore(s) may be in any suitable orientation. For example, the first fluorophore(s) may be over the second fluorophore(s), and the light source may be over the first fluorophore(s). Different orientations may be used for differently situated complementary stacks of fluorophores within the same pair of substrates 199 (e.g., as shown at FIG. 4A). In many embodiments, wavelength λ₁ of the light is an IR wavelength λ₁ (e.g., >700 nm). In some embodiments, wavelength λ₁ of the light is an X-ray wavelength λ₁ (e.g., <10 nm).

Returning to FIG. 3, methods 300 continue by directing emitted light from the first fluorophore at operation 330. The light emitted from the first fluorophore may be directed towards a second fluorophore. The light may be directed by the position and the geometry or shape of the volume containing the first fluorophore(s), for example, as described of alignment plugs 110 at least at FIG. 1. In many embodiments, the first fluorophore absorbs the light (electromagnetic energy) of the first wavelength and re-emits electromagnetic energy (fluoresces) at an intermediate wavelength. The first fluorophore may be chosen for (or fabricated to emit) the intermediate wavelength. The intermediate wavelength λᵢₙₜ is a wavelength at least somewhat longer (e.g., of an at least slightly lower energy) than the first wavelength λ₁ (absorbed by the first fluorophore). The intermediate wavelength λᵢₙₜ will be absorbed by the second fluorophore. The intermediate wavelength λᵢₙₜ is at least somewhat shorter (e.g., of an at least slightly higher energy) than a subsequently emitted wavelength λ₂ (emitted by the second fluorophore). In many embodiments, intermediate wavelength λᵢₙₜ of the light is an IR intermediate wavelength λᵢₙₜ (e.g., >700 nm). In some embodiments, wavelength λᵢₙₜ of the light is an X-ray intermediate wavelength λᵢₙₜ (e.g., <10 nm).

FIG. 4B shows light at wavelength λᵢₙₜ directed upwards from first fluorophores 111A in substrate 199A (e.g., towards second fluorophores 111B in substrate 199B), in accordance with some embodiments, for example, following a performance of directing operation 330.

Returning to FIG. 3, methods 300 continue with directing to the second fluorophore the light emitted from the first fluorophore at operation 340. The light may be directed by the positions and the geometries or shapes of the volumes (e.g., alignment plugs 110) containing the first and second fluorophores. In many embodiments, the second fluorophore absorbs the electromagnetic energy (light) of the intermediate wavelength and re-emits electromagnetic energy at a subsequent wavelength λ₂ (e.g., at least somewhat longer and of an at least slightly lower energy). In many embodiments, subsequent wavelength λ₂ of the light is an IR wavelength λ₂ (e.g., >700 nm). In some embodiments, subsequent wavelength λ₂ of the light is an X-ray wavelength λ₂ (e.g., <10 nm). The second fluorophore may be chosen for (or fabricated to receive) the intermediate wavelength and/or chosen for (or fabricated to emit) the subsequent wavelength λ₂.

FIG. 4B shows second fluorophores 111B in second substrate 199B, over first fluorophores 111A in substrate 199A, receiving light at wavelength λᵢₙₜ and emitting light at wavelength λ₂, in accordance with some embodiments, for example, following a performance of directing operation 340. Second fluorophores 111B are emitting light (at wavelength λ₂) upwards, toward optical detectors 411.

FIG. 4C graphically illustrates the spectral magnitudes of, and compares, the first wavelength λ₁, intermediate wavelength λᵢₙₜ, and subsequent wavelength λ₂. The peak magnitude (or intensity) of the first wavelength λ₁ (from a system light source, and absorbed by the first fluorophore) is at a higher frequency (and shorter wavelength) distinct from the peak intensity of the intermediate wavelength λᵢₙₜ (emitted from the first fluorophore and absorbed by the second fluorophore). The peak intensity of the intermediate wavelength λᵢₙₜ (emitted from the first fluorophore and absorbed by the second fluorophore) is at a higher frequency (and shorter wavelength) distinct from the peak intensity of the subsequent wavelength λ₂ (emitted from the second fluorophore and measured by the optical detector). Each successive light signal is at a longer wavelength (and so lower energy). In many embodiments, the first, intermediate, and subsequent wavelengths λ₁, λᵢₙₜ, λ₂ are all longer than 700 nm. In many embodiments, the first, intermediate, and subsequent wavelengths λ₁, λᵢₙₜ, λ₂ are all shorter than 10 nm.

Returning to FIG. 3, methods 300 continue at operation 350 by detecting the subsequent wavelength λ₂ of electromagnetic energy emitted from the second fluorophore (e.g., in or on the second substrate, and adjacent the first fluorophore). In many embodiments, the detecting the subsequent wavelength λ₂ of electromagnetic energy emitted from the second fluorophore produces an electrical signal with a magnitude proportional to a magnitude of the electromagnetic energy emitted from the second fluorophore (e.g., at the subsequent wavelength λ₂). The detected magnitude may then be analyzed and provide valuable information about the alignment of the IC substrates. For example, by monitoring the change in the magnitude profile as the first and second fluorophores move closer to one another, the detector (and alignment system) will detect a growing (larger) signal, which indicates that the first and second fluorophores (and the first and second substrates) are becoming more closely aligned. Likewise, a shrinking (smaller) signal indicates that the first and second fluorophores (and the first and second substrates) are becoming less aligned.

This detected light magnitude (of the subsequent wavelength λ₂ from the second fluorophore) enables precise alignment of fiducials and fluorophores (and substrates) without complex (e.g., slow and expensive) image processing.

FIG. 4B shows the successive signals from the system light source (first wavelength λ₁), the first fluorophore (intermediate wavelength λᵢₙₜ), and the second fluorophore (subsequent wavelength λ₂) up to photodetectors 411, in accordance with some embodiments, for example, following a performance of detecting operation 350.

FIG. 4D graphically illustrates the emitted intensity of the first fluorophore 111A signals (e.g., intermediate wavelength λᵢₙₜ), in accordance with some embodiments, for example, during a performance of detecting operation 350. Because of the directional nature of the emission profile (of intermediate wavelength λᵢₙₜ), the resulting steep gradient in intensity is mainly a function of the x-and y-positions relative to the first fluorophore 111A in substrate 199A. The steep gradient provides a strong directional (e.g., x- and y-directions) signal of alignment, and the intensity is sufficiently strong in the x- and y-directions (e.g., out to many micrometers) to facilitate the fine alignment provided an initial (e.g., coarse) alignment to within (for example) ~5 μm. An alignment accuracy equal to the size of the spatial extent of fluorophores 111A, 111B may be achieved, given a sufficiently strong and spectrally confined system light source (at first wavelength λ₁) and sufficiently proximate substrates 199A, 199B (e.g., with a vertical or z-separation of 2 mm or less). FIG. 4E shows with greater resolution the detected intensity versus lateral (mis)alignment.

Although FIG. 4D illustrates an emitted intensity profile with a single maximum (e.g., at 0 mm, on a centerline of the single alignment plug 110 and with symmetric roll-off to both sides), other intensity profiles are possible. For example, multiple adjacent plugs 110 may be in a tight array in substrate 199A, and one or more plugs 110 in substrate 199B may be aligned with substrate 199A at a local minimum of the emitted intensity between two or more local maxima of the emitted intensity.

FIG. 4E shows the detected intensity of the final signal (subsequent wavelength λ₂) indicating the relative alignments of substrates 199A, 199B, in accordance with some embodiments, for example, during a performance of detecting operation 350. The line plot in FIG. 4E shows the intensity detected by detector 411 (as shown at FIG. 4D) as a function of lateral distance between top and bottom fluorophores 111A, 111B at fixed vertical height (e.g., ~2 mm). The lateral distance between fluorophores 111A, 111B is shown at both mm- and nm-scales.

Returning to FIG. 3, methods 300 continue at operation 360 with aligning the first and second fluorophores and the first and second substrates using the detected subsequent (e.g., final) wavelength of electromagnetic energy emitted from the second fluorophore. In many embodiments, the aligning the substrates using the detected second wavelength of light emitted from the second fluorophore includes laterally positioning the first or second substrate and increasing the magnitude of the electrical signal by reducing a lateral distance between the first and second fluorophores. The detected intensity may be analyzed to provide information about the alignment of the substrates. Alignment refinement is achieved by observing changes in the detected intensity profile as the top substrate is moved in alignment with the base substrate. The detected intensity profile may exhibit an increase as the fluorophore approaches a closer alignment. The alignment may be considered optimal when the detected intensity reaches its maximum and begins to deviate away from this maximum value. (As described at FIG. 4D, other intensity alignment schemes (e.g., between local maxima) may be used.) The identification of optimal alignment is determined by monitoring the gradient of the intensity profile. The alignment is considered at its peak (optimized) when the gradient approaches minimum and starts deviating negatively (or positively) as the top substrate moves further away from the maximum (or local minimum) intensity position. This precise method of selecting the maximum intensity point is crucial for determining the optimal alignment, indicating the point at which the top substrate is registered for fusion bonding. This dual-alignment process (including the initial positioning, e.g., at operation 310) combines the speed of coarse alignment techniques with the precision offered by the spectral characteristics of fluorophores, resulting in accurate alignment at both macro and nano scales, ultimately facilitating the hybrid bonding of the top substrate (e.g., die) with the base substrate (e.g., wafer or die).

Returning to FIG. 3, methods 300 continue by direct bonding the aligned first and second substrates at operation 370. In many embodiments, the direct bonding of the substrates forms metal-metal and dielectric-dielectric fusion bonds between the substrates. In many embodiments, the IC substrates may be direct bonded, including hybrid bonded. Direct bonding of the substrates may be at least metal-to-metal, for example, during which metallization structures (e.g., interconnect interfaces 131) sinter. In some embodiments, a hybrid bond is formed between both metallization features (e.g., by metal interdiffusion) and between dielectric materials (e.g., by Si—O—Si condensation bonds). Direct, fusion bonding may allow for finer pitch features of the substrates and for coupling the substrates at lower temperatures. For example, thermo-compression bonding may be at low temperatures (e.g., with sintering below the melting temperature(s) of the interconnects). Direct bonding at room temperature (e.g., with compression only) is also possible. Low-temperature bonding may enable the use of less thermally rugged fluorophores (such as organic fluorophores). Selective heating (e.g., as an anneal) may be employed to strengthen a bond (e.g., by interdiffusion between pads). The selective heating may employ a laser or other means to localize heating to a specific region or structure (e.g., the IC substrate).

Direct bonding, particularly at lower temperatures, may benefit from pre-processing (e.g., before alignment), for example, a plasma clean, to activate one or more surfaces for bonding. A surface activation may prepare the substrates for direct bonding. Surface activation before bonding may improve bond strength or enable a reduced anneal temperature and length used to strengthen the bonding. The surface preparation increases the surface energy for bonding the substrates, including bonding of their respective interconnect interfaces. There may be overlap with surface activation and other operations. For example, surface activation may clean substrate surfaces, and planarizing and cleaning operations may activate a substrate surface. Surface activation generally refers to dry cleaning and can be used to remove, e.g., native oxides and adsorbed contaminants. Surface activation may be by, e.g., ultraviolet (UV) and/or ozone cleaning, fast-atom bombardment, or plasma treatments, etc. Plasma activation uses high-voltage and high-frequency stimulation of selected process gases to form a plasma and bombard the substrate surface, often with ions.

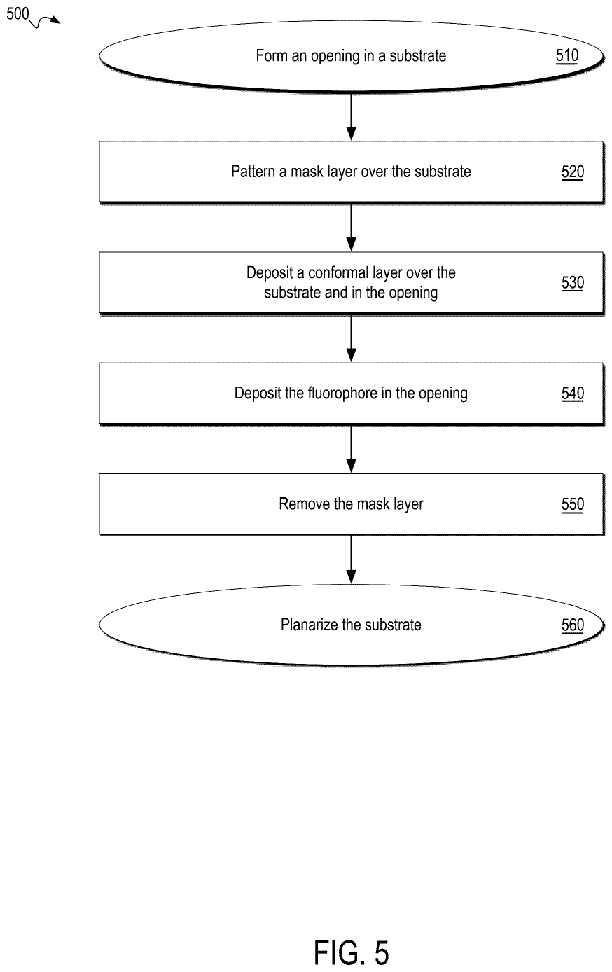

FIG. 5 is a flow chart of methods 500 for forming plugs (or other volumes) containing fluorophores in IC substrates, in accordance with some embodiments. Methods 500 may be used to form (or employ existing) openings to hold fluorophores in IC substrates. Methods 500 include operations 510-560. Some operations shown in FIG. 5 are optional. Additional operations may be included. FIG. 5 shows an example sequence, but the operations can be done in other orders as well, and some operations may be omitted. Some operations can also be performed multiple times before other operations are performed. Some operations may be included within other operations so that the number of operations illustrated FIG. 5 is not a limitation of the methods 500. At operation 510, an opening is formed in the substrate. At operation 520, a mask layer is patterned over the substrate, in some embodiments, leaving the opening exposed, available for processing. At operation 530, a conformal layer is deposited over the substrate and in the opening. At operation 540, a fluorophore is deposited in the opening. At operation 550, the mask layer is removed. At operation 560, the substrate is planarized.

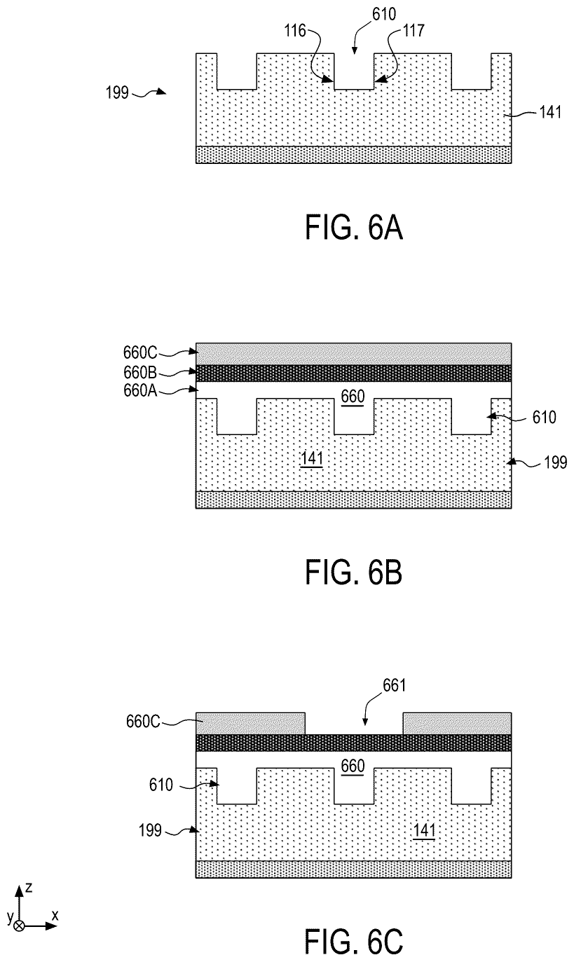

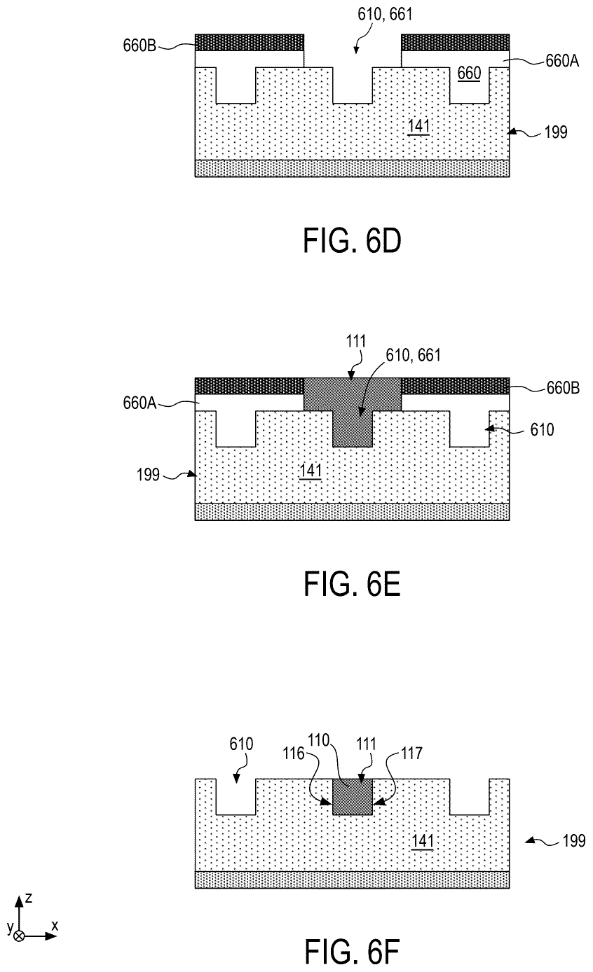

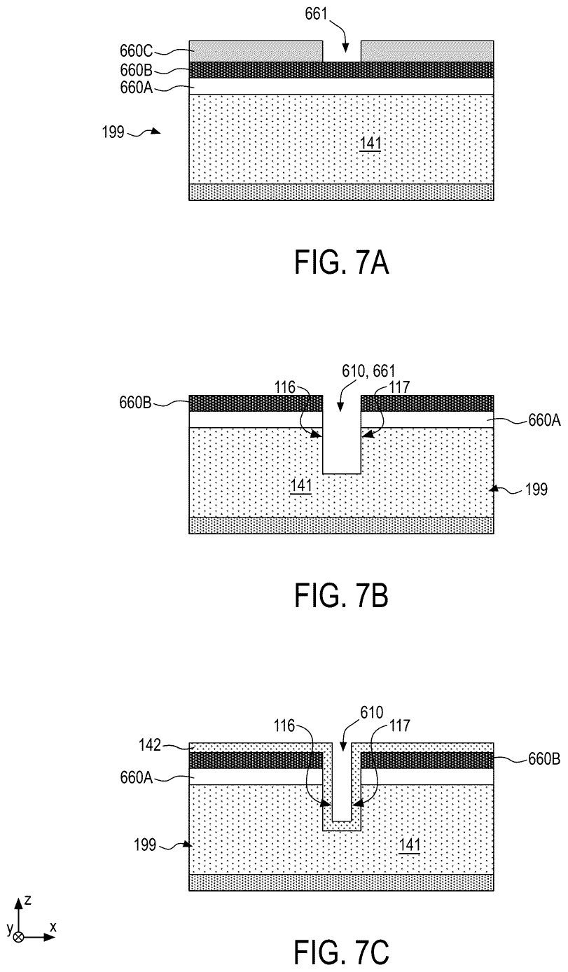

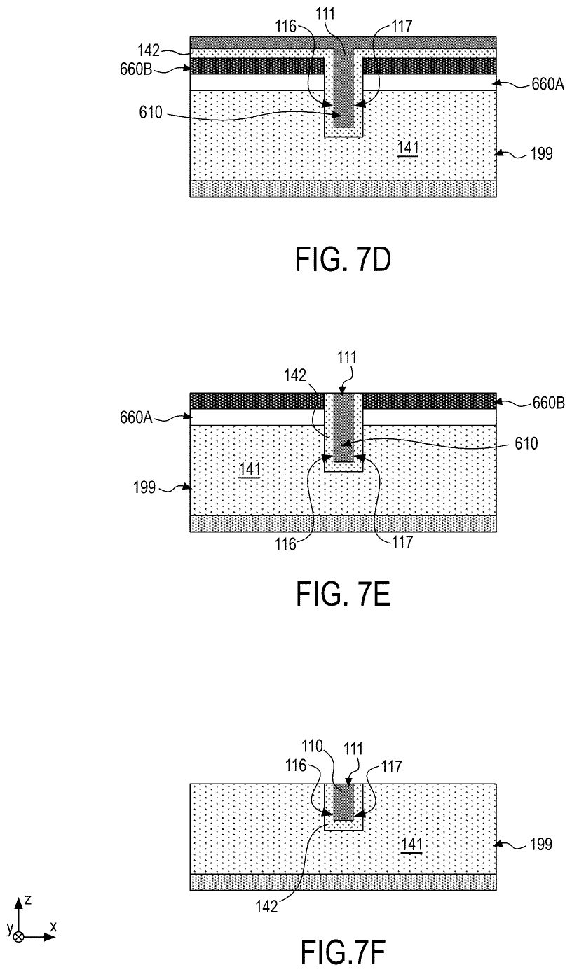

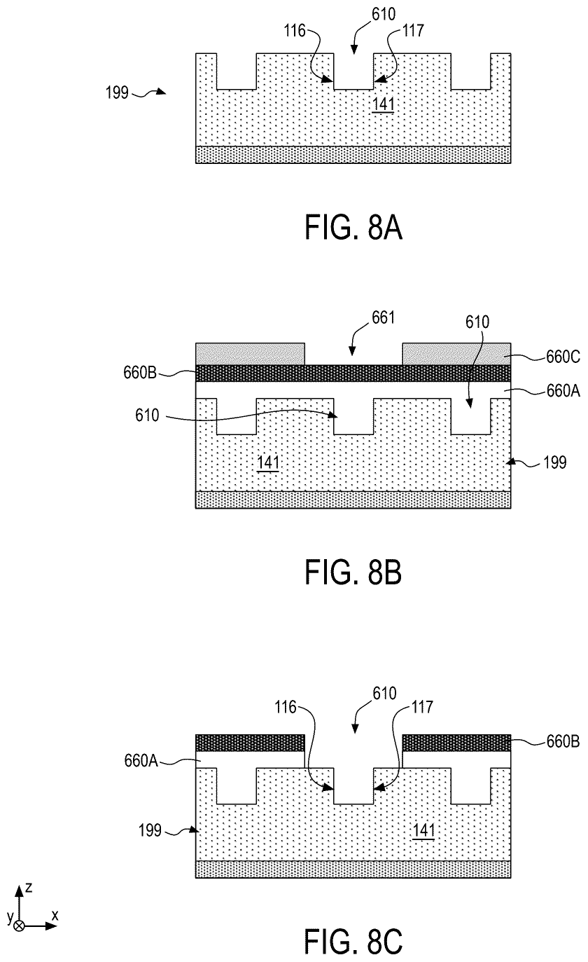

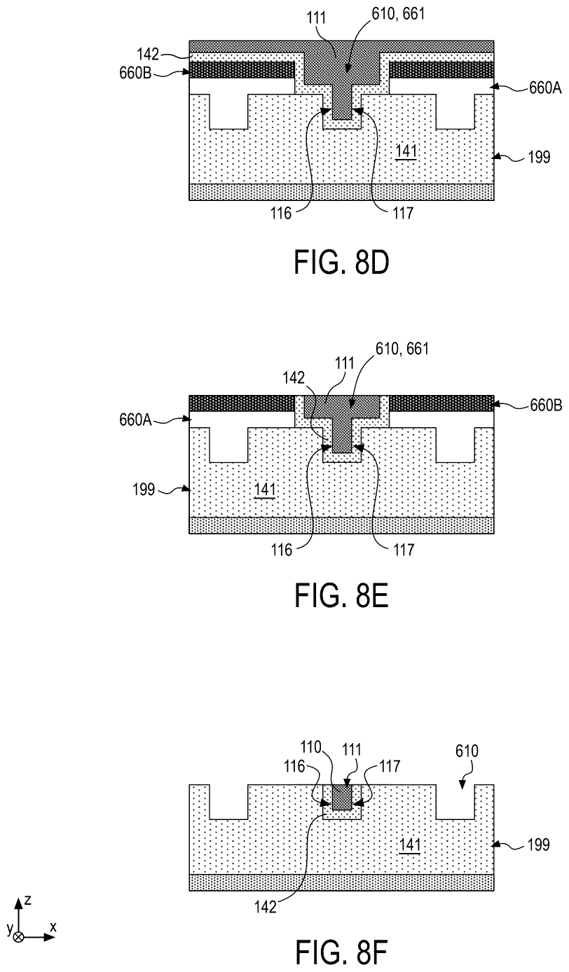

FIGS. 6A, 6B, 6C, 6D, 6E, and 6F illustrate cross-sectional profile views of IC device 100 having an alignment plug 110 containing fluorophores 111 between sidewalls 116, 117 of dielectric layer 141 and IC substrate 199, at various stages of manufacture, in accordance with some embodiments. FIGS. 6A-6F depict an example progression of operations during the fabrication of plug 110 using an existing opening 610 and methods 500, in accordance with some embodiments. In contrast with the progressions shown at FIGS. 7A-7F and 8A-8F, opening 610 at FIGS. 6A-6F is of satisfactory dimensions for containing fluorophores 111 in alignment plug 110. For example, in some embodiments, plug 110 needs to have very small dimensions (e.g., widths in the x-and y-dimensions) requiring the employment of extreme UV (EUV) lithography (or other costly methods), and the progression of FIGS. 6A-6F illustrates operations foregoing the need to form additional expensive openings 610. FIG. 6A shows a substrate 199, e.g., received with existing openings 610 (such as dummy-via holes) in dielectric layer 141. Openings 610 and layer 141 have sidewalls 116, 117.

FIG. 6B illustrates one or more mask layers 660 (e.g., a tri-layer stack of layers 660A, 660B, 660C) over substrate 199 and in openings 610, for example, during a patterning operation 520. In some embodiments, a photoresist layer 660C is over a bottom anti-reflective coating (BARC) layer 660B and a hardmask layer 660A.

FIG. 6C shows layers 660A, 660B, 660C over substrate 199, for example, during a patterning operation 520. An opening 661 is in and through layer 660C, over layers 660A, 660B and one of openings 610. In some embodiments, one or more of openings 610 are to contain fluorophores (e.g., as alignment plugs), for example, as dictated by openings 661 in mask layers 660 over those one or more of openings 610 (and not other openings 610).

FIG. 6D illustrates layers 660A, 660B over substrate 199, for example, following a patterning operation 520. Opening 610 in dielectric layer 141 is exposed in opening 661 through layers 660A, 660B (e.g., transferred down from opening 661 through a removed layer 660C). Layers 660 (e.g., layer 660C) may be removed, e.g., at removing operation 550, by any suitable means, such as a CMP and/or selective etch.

FIG. 6E shows fluorophores 111 (e.g., a significant quantity of fluorophores 111) in openings 610, 661 in layers 660A, 660B and substrate 199, for example, following a depositing operation 540. Fluorophores 111 may be deposited by any suitable means. In some embodiments, fluorophores 111 are mixed in a flowable carrier or coating (e.g., a spin-on dielectric), and the mixture is deposited over substrate 199 (e.g., spun on). An upper surface (e.g., of fluorophores 111 and layer 660B) may be planarized by a CMP, etc., e.g., at planarizing operation 560.

FIG. 6F illustrates alignment plug 110 containing fluorophores 111 in substrate 199. Fluorophores 111 are between sidewalls 116, 117 of dielectric layer 141 and alignment plug 110. Openings 610, such as dummy-via holes, remain in substrate 199 without fluorophore 111.

FIGS. 7A, 7B, 7C, 7D, 7E, and 7F illustrate cross-sectional profile views of IC device 100 having an alignment plug 110 containing fluorophores 111 between sidewalls 116, 117 of dielectric layer 142, at various stages of manufacture, in accordance with some embodiments. FIGS. 7A-7F may depict an example progression of operations, e.g., forming opening 610, during the fabrication of plug 110 by methods 500, in accordance with some embodiments. The progression shown at FIGS. 7A-7F illustrates the fabrication of opening 610 and plug 110 with satisfactorily small dimensions without the use of expensive EUV lithography, e.g., by utilizing a cheaply deposited conformal (or semi-conformal) layer 142. FIG. 7A shows one or more mask layers 660 (e.g., a tri-layer stack of layers 660A, 660B, 660C) over dielectric layer 141 and substrate 199, and an opening 661 in photoresist layer 660C. Opening 661 may be patterned in one or more mask layers 660 by any suitable means, for example, by a patterning operation 520.

FIG. 7B illustrates opening 610 in dielectric layer 141 and opening 661 through layers 660A, 660B, for example, during a forming operation 510 following a patterning operation 520. Opening 610 is exposed in opening 661 through layers 660A, 660B (e.g., transferred down from opening 661 through a removed layer 660C). Layers 660 (e.g., layer 660C) may be removed, e.g., at removing operation 550, by any suitable means, such as a CMP and/or selective etch. Opening 610 has sidewalls 116, 117 of dielectric layer 141.

FIG. 7C shows smaller opening 610 between sidewalls 116, 117 of dielectric layer 142, for example, following a depositing operation 530. Dielectric layer 142 is conformally (or semi-conformally) over substrate 199 (e.g., layers 660A, 660B) and over and in opening 610. Dielectric layer 142 may be deposited by any suitable means, such as an ALD (atomic layer deposition) or a less-expensive CVD (chemical vapor deposition) or PVD (physical vapor deposition), e.g., at depositing operation 530. Sidewalls 116, 117 of opening 610 and dielectric layer 142 are separated by a shorter distance than were the sidewalls of dielectric layer 141. Opening 610 is smaller (e.g., narrower) and the separation between sidewalls 116, 117 is reduced by twice the thickness of dielectric layer 142.

FIG. 7D illustrates fluorophores 111 (e.g., a significant quantity of fluorophores 111) over and between dielectric layer 142, in opening 610 in substrate 199 and over substrate 199 (e.g., layers 660A, 660B), for example, following a depositing operation 540. Fluorophores 111 may be deposited by any suitable means. In some embodiments, fluorophores 111 are spun onto substrate 199, mixed into a flowable (e.g., spin-on) dielectric coating.

FIG. 7E shows fluorophores 111 in opening 610 in substrate 199, between sidewalls 116, 117 of dielectric layer 142, but not over layers 660A, 660B, for example, following a planarizing operation 560 (e.g., that removed layer 142 and fluorophores 111 over layers 660A, 660B). Dielectric layer 142 is conformally in opening 610 of layer 141 and substrate 199 and of layers 660A, 660B.

FIG. 7F illustrates alignment plug 110 containing fluorophores 111 in substrate 199. Fluorophores 111 are between sidewalls 116, 117 of dielectric layer 142 and alignment plug 110. Layers 660 (e.g., layers 660A, 660B) are removed, e.g., by a removing operation 550, by any suitable means, such as a CMP and/or selective etch.

FIGS. 8A, 8B, 8C, 8D, 8E, and 8F illustrate cross-sectional profile views of IC device 100 having an alignment plug 110 containing fluorophores 111 between sidewalls 116, 117 of dielectric layer 142, at various stages of manufacture, in accordance with some embodiments. FIGS. 8A-8F depict an example progression of operations during the fabrication of plug 110 using an existing opening 610 and methods 500, in accordance with some embodiments, for example, to make alignment plug 110 smaller than opening 610 with a conformal or semi-conformal dielectric layer 142. FIG. 8A shows substrate 199, e.g., received with existing openings 610 (such as dummy-via holes) in dielectric layer 141. Openings 610 and layer 141 have sidewalls 116, 117.

FIG. 8B illustrates one or more mask layers 660 (e.g., a tri-layer stack of layers 660A, 660B, 660C) over substrate 199 and in openings 610, for example, during a patterning operation 520. In some embodiments, a photoresist layer 660C is over a bottom anti-reflective coating (BARC) layer 660B and a hardmask layer 660A. Opening 661 is in and through layer 660C, over layers 660A, 660B and one of openings 610. In some embodiments, one or more of openings 610 are to contain fluorophores (e.g., as alignment plugs), for example, as dictated by openings 661 in mask layers 660 over those one or more of openings 610 (and not other openings 610).

FIG. 8C shows layers 660A, 660B over substrate 199, for example, following a patterning operation 520. Opening 610 in dielectric layer 141 is exposed in opening 661 through layers 660A, 660B (e.g., transferred down from opening 661 through a removed layer 660C). Layers 660 (e.g., layer 660C) may be removed, e.g., at removing operation 550, by any suitable means, such as a CMP and/or selective etch. Openings 610 and layer 141 have sidewalls 116, 117.

FIG. 8D illustrates fluorophores 111 (e.g., a significant quantity of fluorophores 111) over and between dielectric layer 142, in openings 610, 661 in layers 660A, 660B and substrate 199, for example, following depositing operations 530, 540. Layer 142 may be deposited by any suitable means. Fluorophores 111 are between sidewalls 116, 117 of dielectric layer 142 in opening 610. Sidewalls 116, 117 of opening 610 and dielectric layer 142 are separated by a shorter distance than were the sidewalls of dielectric layer 141. Opening 610 is smaller (e.g., narrower) and the separation between sidewalls 116, 117 is reduced by twice the thickness of dielectric layer 142. Fluorophores 111 may be deposited by any suitable means. In some embodiments, fluorophores 111 are spun onto substrate 199, mixed into a flowable (e.g., gap-filling) dielectric coating.

FIG. 8E shows fluorophores 111 in opening 610 in substrate 199, between sidewalls 116, 117 of dielectric layer 142, but not over layers 660A, 660B, for example, following a planarizing operation 560 (e.g., that removed layer 142 and fluorophores 111 over layers 660A, 660B). Dielectric layer 142 is conformally in opening 610 of layer 141 and substrate 199 and of layers 660A, 660B.

FIG. 8F illustrates alignment plug 110 containing fluorophores 111 in substrate 199. Fluorophores 111 are between sidewalls 116, 117 of dielectric layer 142 and alignment plug 110. Openings 610, such as dummy-via holes, remain in substrate 199 without fluorophore 111. Layers 660 (e.g., layers 660A, 660B) are removed, e.g., by a removing operation 550, by any suitable means, such as a CMP and/or selective etch.

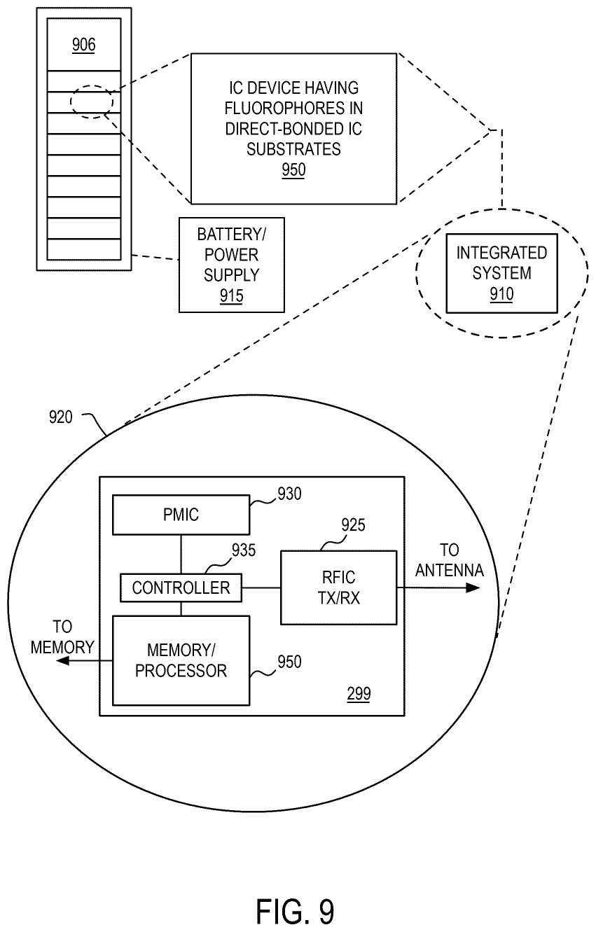

FIG. 9 illustrates a diagram of an example data server machine 906 employing an IC device having fluorophores in direct-bonded substrates, in accordance with some embodiments. Server machine 906 may be any commercial server, for example, including any number of high-performance computing platforms disposed within a rack and networked together for electronic data processing, which in the exemplary embodiment includes one or more devices 950 having fluorophores in direct-bonded IC substrates.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device having fluorophores in direct-bonded substrates, as discussed herein. Device 950 may be further coupled to (e.g., communicatively coupled to) a board, an interposer, or other substrate or host component 299 along with, one or more of a power management IC (PMIC) 930, RF (wireless) IC (RFIC) 925 including a wideband RF (wireless) transmitter and/or receiver (TX/RX) (e.g., including a digital baseband and an analog front-end module further includes a power amplifier on a transmit path and a low noise amplifier on a receive path), and a controller 935 thereof. In some embodiments, RFIC 925, PMIC 930, controller 935, and device 950 include fluorophores in direct-bonded IC substrates.

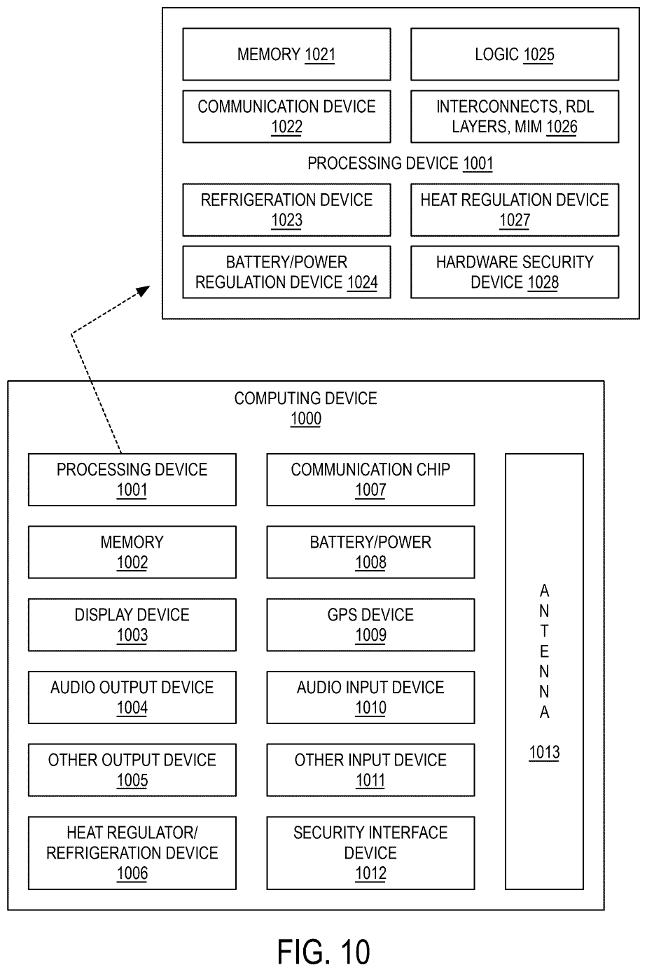

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes an IC substrate, including a dielectric layer, and a fluorescent layer in the IC substrate, the fluorescent layer between first and second sidewalls of the dielectric layer.

In one or more second embodiments, further to the first embodiments, the fluorescent layer includes a fluorophore including arsenic and at least one of gallium and indium.

In one or more third embodiments, further to the first or second embodiments, the fluorophore is a quantum dot including arsenic and at least one of gallium and indium.

In one or more fourth embodiments, further to the first through third embodiments, the fluorescent layer is in a volume of a dielectric material between the first and second sidewalls, and the first and second sidewalls are separated by a distance of 30 nm or less.

In one or more fifth embodiments, further to the first through fourth embodiments, the IC substrate is a first IC substrate, and the fluorescent layer is a first fluorescent layer, the apparatus also including a second IC substrate coupled to the first IC substrate, the second IC substrate including a second fluorescent layer adjacent the first fluorescent layer.

In one or more sixth embodiments, further to the first through fifth embodiments, the first IC substrate includes a third fluorescent layer, the first and third fluorescent layer separated by a first distance, and the second IC substrate includes a fourth fluorescent layer, the second and fourth fluorescent layer separated by a second distance approximately equal to the first distance.

In one or more seventh embodiments, further to the first through sixth embodiments, the first IC substrate includes a third fluorescent layer, the second IC substrate includes a fourth fluorescent layer, the first and second fluorescent layer are vertically aligned, and the third and fourth fluorescent layer are vertically aligned.

In one or more eighth embodiments, further to the first through seventh embodiments, the first and second IC substrates are coupled by direct bonds.

In one or more ninth embodiments, further to the first through eighth embodiments, the fluorescent layer is capable of absorbing energy at a first wavelength, and emitting energy at a second wavelength, the second wavelength longer than the first wavelength, and the first and second wavelengths are both longer than 700 nm or both shorter than 10 nm.

In one or more tenth embodiments, further to the first through ninth embodiments, the IC substrate is a first IC substrate coupled with a second IC substrate, and the first IC substrate is coupled with a power supply through the second IC substrate.

In one or more eleventh embodiments, an apparatus includes a first fluorescent plug on a first substrate, and a second fluorescent plug on a second substrate, the second substrate coupled to the first substrate, the second fluorescent plug adjacent the first fluorescent plug, wherein the first and second substrates are integrated circuit substrates.

In one or more twelfth embodiments, further to the eleventh embodiments, the first substrate is direct bonded with the second substrate.

In one or more thirteenth embodiments, further to the eleventh or twelfth embodiments, the first fluorescent plug includes arsenic and at least one of gallium and indium, and the second fluorescent plug includes arsenic and at least one of gallium and indium.

In one or more fourteenth embodiments, further to the eleventh through thirteenth embodiments, the first substrate is coupled with a third substrate, and the first substrate is coupled with a power supply through the third substrate.

In one or more fifteenth embodiments, a method including radiating a first fluorophore in or on a first substrate with a first wavelength of electromagnetic energy, detecting a second wavelength of electromagnetic energy emitted from a second fluorophore in or on a second substrate, the second fluorophore adjacent the first fluorophore, and aligning the first and second fluorophores and the first and second substrates using the detected second wavelength of electromagnetic energy emitted from the second fluorophore.

In one or more sixteenth embodiments, further to the fifteenth embodiments, the first fluorophore absorbs electromagnetic energy of the first wavelength and re-emits electromagnetic energy at a third wavelength, and the second fluorophore absorbs electromagnetic energy of the third wavelength and re-emits electromagnetic energy at the second wavelength.

In one or more seventeenth embodiments, further to the fifteenth or sixteenth embodiments, the first, second, and third wavelengths are all longer than 700 nm or all shorter than 10 nm.

In one or more eighteenth embodiments, further to the fifteenth through seventeenth embodiments, the method also includes direct bonding the aligned first and second substrates, wherein the direct bonding the aligned first and second substrates includes forming metal-metal and dielectric-dielectric fusion bonds between the aligned first and second substrates.

In one or more nineteenth embodiments, further to the fifteenth through eighteenth embodiments, the detecting the second wavelength of electromagnetic energy emitted from the second fluorophore produces an electrical signal with a first magnitude proportional to a second magnitude of the electromagnetic energy emitted from the second fluorophore, and the aligning the first and second fluorophores and the first and second substrates using the detected second wavelength of electromagnetic energy emitted from the second fluorophore includes laterally positioning the first or second substrate, and increasing the first magnitude of the electrical signal by reducing a lateral distance between the first and second fluorophores.

In one or more twentieth embodiments, further to the fifteenth through nineteenth embodiments, the aligning the first and second fluorophores and the first and second substrates is a fine aligning, the method also including initially aligning the second fluorophore to adjacent the first fluorophore.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
an integrated circuit (IC) substrate, comprising a dielectric layer; and
a fluorescent layer in the IC substrate, the fluorescent layer between first and second sidewalls of the dielectric layer.

2. The apparatus of claim 1, wherein the fluorescent layer comprises a fluorophore comprising arsenic and at least one of gallium and indium.

3. The apparatus of claim 2, wherein the fluorophore is a quantum dot comprising arsenic and at least one of gallium and indium.

4. The apparatus of claim 1, wherein the fluorescent layer is in a volume of a dielectric material between the first and second sidewalls, and the first and second sidewalls are separated by a distance of 30 nm or less.

5. The apparatus of claim 1, wherein the IC substrate is a first IC substrate, and the fluorescent layer is a first fluorescent layer, further comprising a second IC substrate coupled to the first IC substrate, the second IC substrate comprising a second fluorescent layer adjacent the first fluorescent layer.

6. The apparatus of claim 5, wherein the first IC substrate comprises a third fluorescent layer, the first and third fluorescent layer separated by a first distance, and the second IC substrate comprises a fourth fluorescent layer, the second and fourth fluorescent layer separated by a second distance approximately equal to the first distance.

7. The apparatus of claim 5, wherein the first IC substrate comprises a third fluorescent layer, the second IC substrate comprises a fourth fluorescent layer, the first and second fluorescent layer are vertically aligned, and the third and fourth fluorescent layer are vertically aligned.

8. The apparatus of claim 5, wherein the first and second IC substrates are coupled by direct bonds.

9. The apparatus of claim 1, wherein:
the fluorescent layer is capable of:
absorbing energy at a first wavelength; and
emitting energy at a second wavelength, the second wavelength longer than the first wavelength; and
the first and second wavelengths are both longer than 700 nm or both shorter than 10 nm.

10. The apparatus of claim 1, wherein the IC substrate is a first IC substrate coupled with a second IC substrate, and the first IC substrate is coupled with a power supply through the second IC substrate.

11. An apparatus, comprising:
a first fluorescent plug on a first substrate; and
a second fluorescent plug on a second substrate, the second substrate coupled to the first substrate, the second fluorescent plug adjacent the first fluorescent plug, wherein the first and second substrates are integrated circuit substrates.

12. The apparatus of claim 11, wherein the first substrate is direct bonded with the second substrate.

13. The apparatus of claim 12, wherein:
the first fluorescent plug comprises arsenic and at least one of gallium and indium; and
the second fluorescent plug comprises arsenic and at least one of gallium and indium.

14. The apparatus of claim 11, wherein the first substrate is coupled with a third substrate, and the first substrate is coupled with a power supply through the third substrate.

15. A method comprising:
radiating a first fluorophore in or on a first substrate with a first wavelength of electromagnetic energy;
detecting a second wavelength of electromagnetic energy emitted from a second fluorophore in or on a second substrate, the second fluorophore adjacent the first fluorophore; and
aligning the first and second fluorophores and the first and second substrates using the detected second wavelength of electromagnetic energy emitted from the second fluorophore.

16. The method of claim 15, wherein:
the first fluorophore absorbs electromagnetic energy of the first wavelength and re-emits electromagnetic energy at a third wavelength; and
the second fluorophore absorbs electromagnetic energy of the third wavelength and re-emits electromagnetic energy at the second wavelength.

17. The method of claim 16, wherein the first, second, and third wavelengths are all longer than 700 nm or all shorter than 10 nm.

18. The method of claim 15, further comprising direct bonding the aligned first and second substrates, wherein the direct bonding the aligned first and second substrates comprises forming metal-metal and dielectric-dielectric fusion bonds between the aligned first and second substrates.

19. The method of claim 15, wherein:
the detecting the second wavelength of electromagnetic energy emitted from the second fluorophore produces an electrical signal with a first magnitude proportional to a second magnitude of the electromagnetic energy emitted from the second fluorophore; and
the aligning the first and second fluorophores and the first and second substrates using the detected second wavelength of electromagnetic energy emitted from the second fluorophore comprises:
laterally positioning the first or second substrate; and
increasing the first magnitude of the electrical signal by reducing a lateral distance between the first and second fluorophores.

20. The method of claim 15, wherein the aligning the first and second fluorophores and the first and second substrates is a fine aligning, further comprising initially aligning the second fluorophore to adjacent the first fluorophore.
